(19) United States
(12) Patent Application Publication
(10) Pub. No.: US 2013/0118271 A1
(43) Pub. Date: May 16, 2013

(54) SENSOR SIGNAL SAMPLING

(71) Applicants: Edward Colby, Cambridge (GB); Matthew Storkey, Trumpington (GB); David Healy, Stowmarket (GB); Konstantin Stefanov, Milton (GB)

(72) Inventors: Edward Colby, Cambridge (GB); Matthew Storkey, Trumpington (GB); David Healy, Stowmarket (GB); Konstantin Stefanov, Milton (GB)

(73) Assignee: SENTEC LTD., Cambridge, Cambridgeshire (GB)

(21) Appl. No.: 13/806,009

(22) PCT Filed: Jun. 24, 2011
(86) PCT No.: PCT/GB2011/051200

§ 371 Date: Jan. 31, 2013

(30) Foreign Application Priority Data
Jun. 25, 2010 (GB) 1010691.2

(51) Int. Cl. H03K 3/01; G01F 1/56

(52) U.S. Cl. CPC H03K 3/01; G01F 1/56
USPC 73/861.08; 327/91

(57) ABSTRACT

A system for processing a signal from a sensor is described. The system comprises an analog-to-digital converter. The system is configured to vary a sampling rate of said analog-to-digital converter dependent on an expected shape of the signal.

### FIELD OF THE INVENTION

The present invention relates to sensor signal sampling.

### SUMMARY

According to a first aspect of the present invention there is provided a system for processing a signal from a sensor, the system comprising an analog-to-digital converter, wherein the system is configured to vary, for example decreasing, a sampling rate of said analog-to-digital converter dependent on an expected shape of the signal.

By varying the sampling rate, the number of samples for a given signal can be reduced. Reducing the number of samples can help to save power. Reducing the number of samples can also help to reduce the amount of processing power and memory used.

The system may include a controller configured to provide a signal to the analog-to-digital converter so as vary the sampling rate. The signal may trigger the analog-to-digital converter to take a sample.

A sample time, tₙ, of an n-th sample (n being a positive integer) may follow a relationship:
tₙ=func(n)
   where func(n) is a monotonic function, for example, an increasing monotonic function, over the course of the signal. The function may be chosen such that a number (N+1) of desired sample points within a top half of a signal peak is preferably between 3 and 10 or more preferably between 3 and 5.

Sample times may increase at a rate faster than arithmetic progression, e.g. at a geometric rate.

The time interval, Δtₙ₊₁, between an n-th and (n+1)-th sample may be:

Δtₙ₊₁Δtₙ+cn

where Δtₙ is the time interval between an (n−1)-th and n-th samples and c is positive, i.e. c>0.

A sample time, tₙ, of an n-th sample (n being a positive integer) may follow the relationship:

tₙ=a+t₀e^{kn}

where a is an offset which can be zero, i.e. a=0, or positive, i.e. a>0, t₀ is an initial sample time and k is greater than 0, i.e. k>0. The value k may be computed using:

$$k = \frac{1}{N} \cdot log ( \frac{{t}_{B}}{{t}_{A}} )$$

where (N+1) is a number of desired sample points within a top half of a signal peak lying between expected values t_{A} and t_{B}. The value of (N+1) may be at least 3. The value of (N+1) may be no more than 10 and, optionally, no more than 5.

The value of k may be no more than 0.5 and, optionally, no more than about 0.3. The value of k may be greater than 0.05.

A sample time, tₙ, of an n-th sample (n being a positive integer) may follow the relationship:

tₙ=a+t₀kⁿ

where a is an offset which can be zero, i.e. a=0, or positive, i.e. a>0, t₀ is an initial sample time and k is greater than 1, i.e. k>1. The value of k may be computed such that a number (N+1) of desired sample points within a top half of a signal peak is preferably between 3 and 10 or more preferably between 3 and 5.

A sample time, tₙ, of an n-th sample (n being a positive integer) may follow the relationship:

tₙ=a+t₀n^{p}

where a is an offset which can be zero, i.e. a=0, or positive, i.e. a>0, t₀ is an initial sample time and p is greater than 1, i.e. p>1.

The system may be or comprise a microcontroller.

According to a second aspect of the present invention there is provided apparatus comprising a sensor and the system for processing a signal from a sensor, wherein the system is operatively connected to the sensor such that, when the sensor generates a signal, the signal is received by the analog-to-digital convertor.

The apparatus may be a flow meter.

According to a third aspect of the present invention there is provided a method comprising receiving an analog signal and digitally sampling the analog signal, wherein the analog signal is sampled at a varying sample rate which depends on an expected shape of the signal.

A time interval between samples may increase monotonically.

According to a fourth aspect of the present invention there is provided a sensor and signal processing system incorporating an analog to digital converter wherein the sample rate of said analog to digital converter is varied with time to match the expected bandwidth of the signal emitted by the sensor.

### BRIEF DESCRIPTION OF THE DRAWINGS

Certain embodiments of the present invention will now be described, by way of example, with reference to the accompanying drawings, in which:

FIG. 1 illustrates an example of an averaged signal pulse from an ionisation flow meter system;

FIG. 2 illustrate idealised pulses during a time-of-flight measurement;

FIG. 3 illustrates sampling of the idealised pulses shown in FIG. 2 using a uniform sampling rate;

FIG. 4 is a plot of measured pulse width as a function of time of flight;

FIG. 5 illustrates sampling of an idealised narrow pulse shown in FIG. 2 using a non-uniform sampling rate;

FIG. 6 illustrates sampling of an idealised wide pulse shown in FIG. 2 using a non-uniform sampling rate;

FIG. 7 is a plot of system error as a function of the value of k;

FIG. 8 illustrates the averaged signal pulse shown in FIG. 1 with non-uniform sampling points; and

FIG. 9 is schematic block diagram of an ionisation flow meter system.

### DETAILED DESCRIPTION OF CERTAIN EMBODIMENTS

Ionisation Flow Meter

An ionisation flow meter measures the time taken for an ionised cloud of gas to travel between two points within a flow tube, the first point being defined by a modulation grid, the second point being defined by a detector grid. The modulator grid modulates the polarity of the ionised gas cloud. Changes in the polarity are detected at the detector grids and the time of flight for the ionisation transition to reach the detector grid from the modulation grid is measured. This measured time of flight is then used to calculate a volumetric flow rate of gas passing through the system at a given time. An example of an ionisation flow meter is described in WO 2007 068869 A which is incorporated herein by reference.

Signal Characteristics

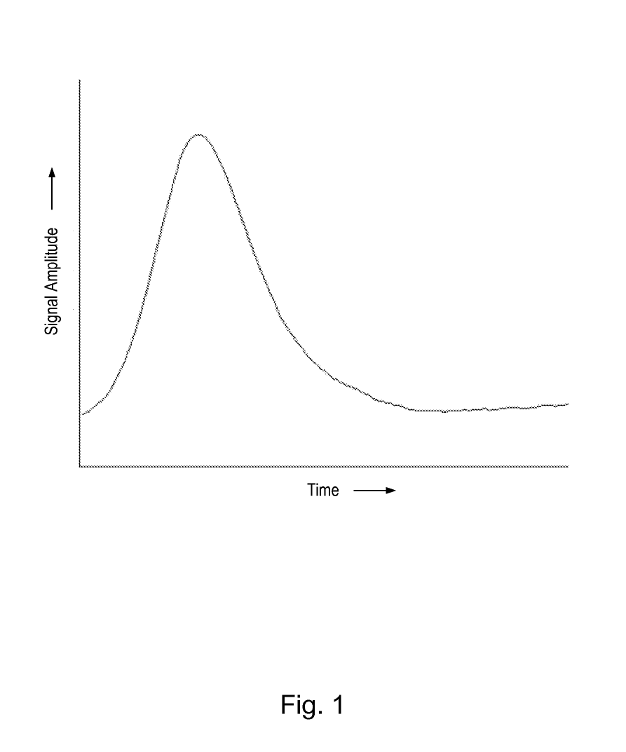

Detection of the change in cloud ionisation uses the principle of mirror charges and sensing electronics to measure the current flowing on to or off of the detector grid. As the ionisation change approaches the detector grid a steadily increasing current flows and increasing signal amplitude is observed. Peak current and peak signal amplitude is observed at the point the ionisation transition passes the detector grid. As the transition edge continues to move away from the detector grid the current decreases as does the observed signal amplitude. Finding the time at which the signal peaks allows the time of flight of the ionisation transition to be determined and hence the volumetric flow rate. FIG. 1 shows an averaged signal pulse observed at the detector grids. The signal has been averaged over a number of modulator transitions to reduce the amount of noise observed.

Peak Position Determination

Sampling the detected signal with a sufficiently small sample period will allow the peak time to be approximated as simply the time of the peak sample. A longer sample period, and thus fewer samples and lower power consumption, can be used if curve fitting techniques are used to determine the peak position. Approximating the region around the signal peak as a quadratic and fitting this to the sampled data points provides a good estimation of the peak position.

Pulse Width Variation

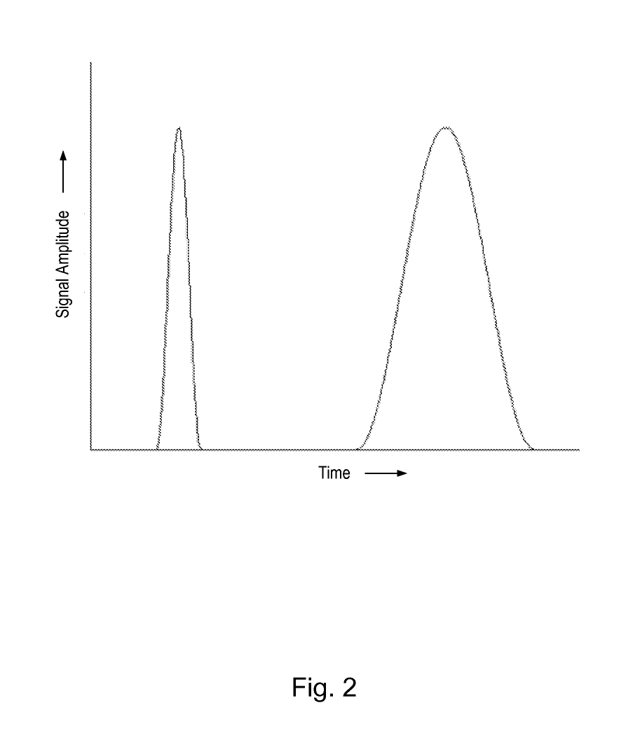

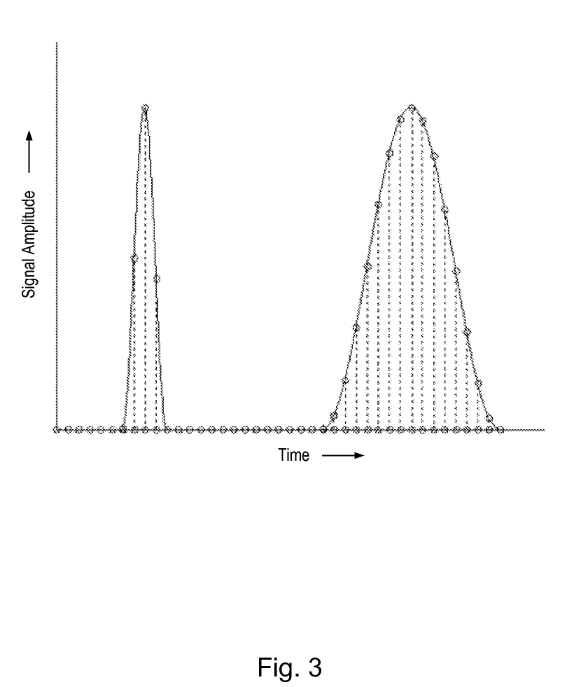

Observation of the detected pulses within the ionisation flow meter system shows that the pulse width varies with the time of flight such that the pulse becomes wider as the time of flight increases as shown in the idealised pulses in FIG. 2. Therefore, any uniform sampling regime has to have a sample period sufficiently small to allow resolution of the narrowest expected pulse width at the shortest expected time of flight. This results in redundancy in sampling of wider pulses with a longer time of flight and a wasted effort in capturing these redundant samples as shown in FIG. 3.

Using a non-uniform sample interval based on the observed relationship between pulse width and time of flight offers the benefit of reducing the number of sample points captured while maintaining the accuracy of peak position measurement. Depending upon the non-uniform sampling regime used a secondary benefit is provided in making the data sampled in the non-uniform manner appear similar to subsequent processing routines.

Determination of Non-Uniform Sample Intervals

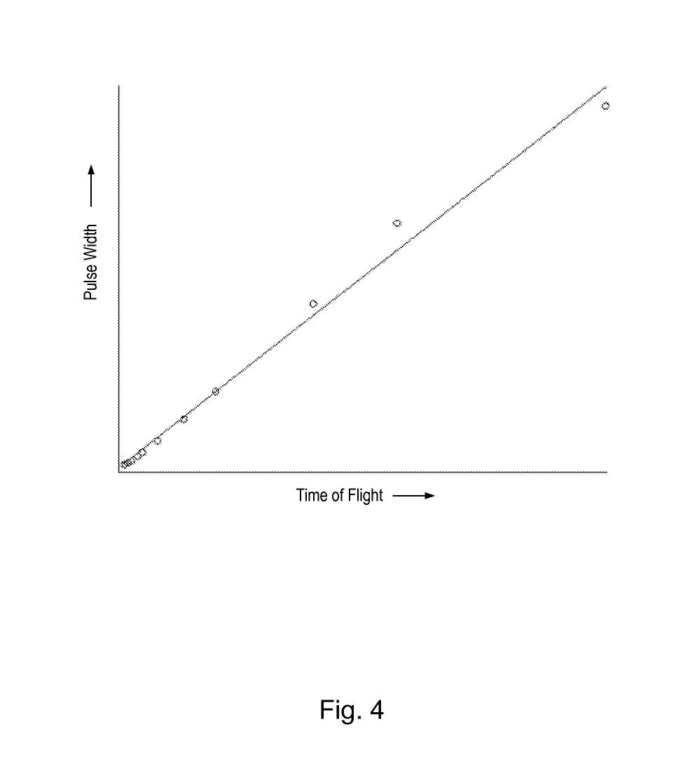

In order to determine the optimal non-uniform sample intervals it is necessary to quantify the relationship between pulse width and time of flight. Observation of signals within the ionisation flow meter system indicate that the relationship between pulse width and time of flight is approximately linear with pulse width being approximately proportional to the time of flight as shown in FIG. 4. This observation leads to the conclusion that the sample period should increase in a similar manner such that the time between sample n and sample (n+1) is a function of n. The sample times should increase at a rate faster than arithmetic progression, which corresponds to uniform periodic sampling.

One possible determination of the sampling intervals could be derived if we assume that the sampling period is proportional to the number of the ADC sample:

Δtₙ=tₙ₊₁−tₙ=ktₙ (1)

Comparing this difference equation in n with the differential equation:

$$\frac{d {t}_{n}}{d n} = {kt}_{n}$$

leads to the solution for the sample times as:
tₙ=t₀e^{kn}
   where t₀ is the time of the initial sample required and the value of k is chosen to give the desired resolution and determines the number of sample points used.

Another possible determination of the sampling intervals is to use geometric progression:
tₙ=t₀kⁿ
   and

Δtₙ=t₀(kⁿ−kⁿ⁻¹) (2)

Many other sequences of sampling times could be used is they satisfy the conditions that the interval between consecutive sample should be an increasing monotonic function of the sample number:
Δtₙ>Δtₙ₋₁
   and
tₙ=func(n)

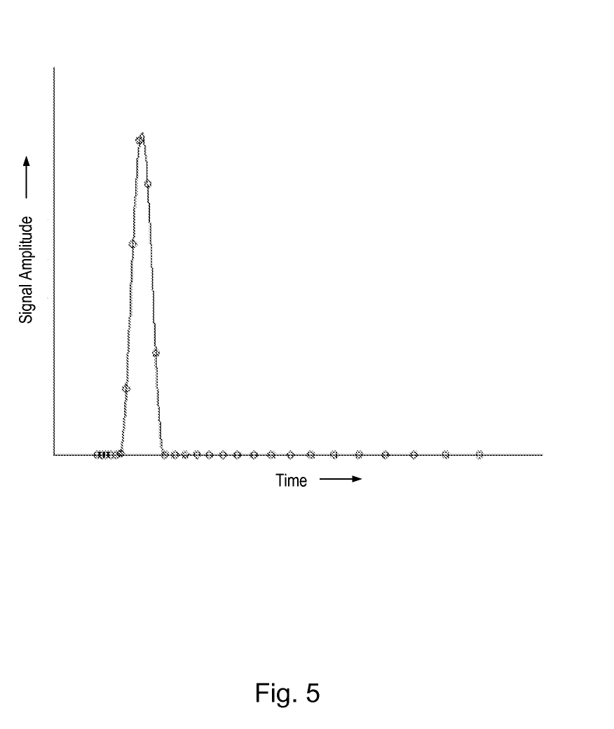

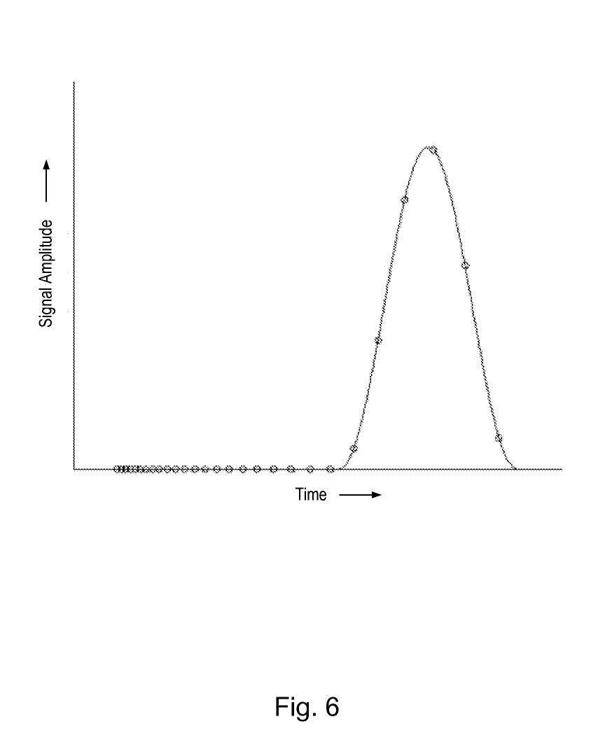

Using a non-uniform sample interval as described above results in the sample points shown in FIG. 5 and FIG. 6 being used for the two idealised pulses. The redundancy seen when using uniform sampling has been removed. Non-uniform sampling has reduced the number of sample points while maintaining sufficient points within the signal peak region to resolve that peak and estimate the peak position by fitting a quadratic curve.

Determination of k

The value of k in the equation
tₙ=t₀e^{kn}
   determines the number of points in a given time interval and thus the resolution of the sampling regime at a specific point in time. A lower k indicates a lower sample interval, a higher resolution and a larger number of sample points. The value of k needs to be selected such that the benefit of fewer sample points does not result in there not being enough data to estimate the signal peak accurately.

Suppose a pulse of 50 ms width, measured at half the peak amplitude, arrives with peak at 200 ms and there needs to be four points within the top half of the signal peak in order to obtain an accurate estimate of the peak position. k can be calculated by observing that t₀=175 ms, t_{N}=225 ms and N=3 and that:

$$k = \frac{1}{N} \cdot log ( \frac{{t}_{N}}{{t}_{0}} )$$

giving a value of k=0.084. This value of k is that used in determining the sample points for FIG. 5 and FIG. 6.

For points derived from geometric progression k would be:

$$k = {( \frac{{t}_{n}}{{t}_{0}} )}^{1 / n}$$

Corresponding parameters for other functions can be found in a similar way, that is, by determining the values of the parameters which provides a suitable number of points within the top half of a signal peak. A suitable number of points may be between three and ten points or, preferably, between three and five points.

Measurement Error

If the pulse peak is accurately described by the curve being fitted to the sampled data and there are sufficient sample points within the region of the pulse conforming to the fitted curve it is possible to accurately recover the peak shape and thus the peak position without any error. However, if the fitted curve is an approximation to the shape of the pulse over the region sampled around the peak there will be errors introduced. Careful choice of parameters for the non-uniform sample points is required to ensure that the benefit of fewer sample points is not out weighted by the introduction of errors.

Experimental Data

Test data from the ionisation flow meter system was analysed using the non-uniform sampling and curve fitting technique described above to measure pulse time of flight with varying value for k corresponding to varying numbers of sample points. The time of flight was used to calculate a flow rate which was compared to the known flow rates used as for the testing. Differences between calculated and known flow rates were combined using a root-mean-square approach to produce a single error figure that can be used as a measure of merit for the signal processing system.

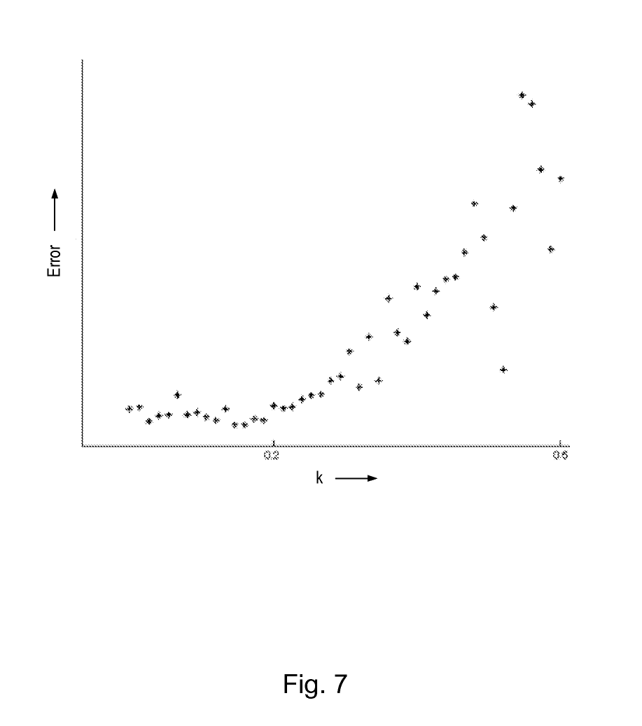

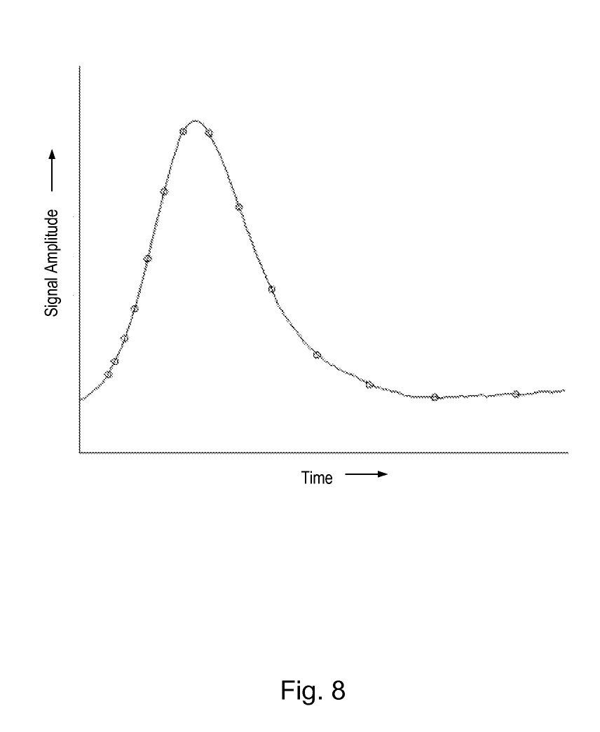

FIG. 7 shows how the error value changes for different k values. A low k gives a low error value at the expense of a larger number of sample points. As k increases the error remains low until a threshold is reached, at which point the error begins to increase. This threshold corresponds to the point at which there are insufficient sample points within the peak region of the signal pulse to accurately determine the peak position. As k continues to increase the spread of error values begins to increase indicating the further decrease in signal processing performance. In the system tested it can be seen that the optimum value for k is approximately 0.2. FIG. 8 shows the sample points used with k=0.2 and the averaged signal from FIG. 1 showing that this corresponds to a low number of samples being required while still resolving the signal peak and thus time of flight.

Signal Processing Arrangement

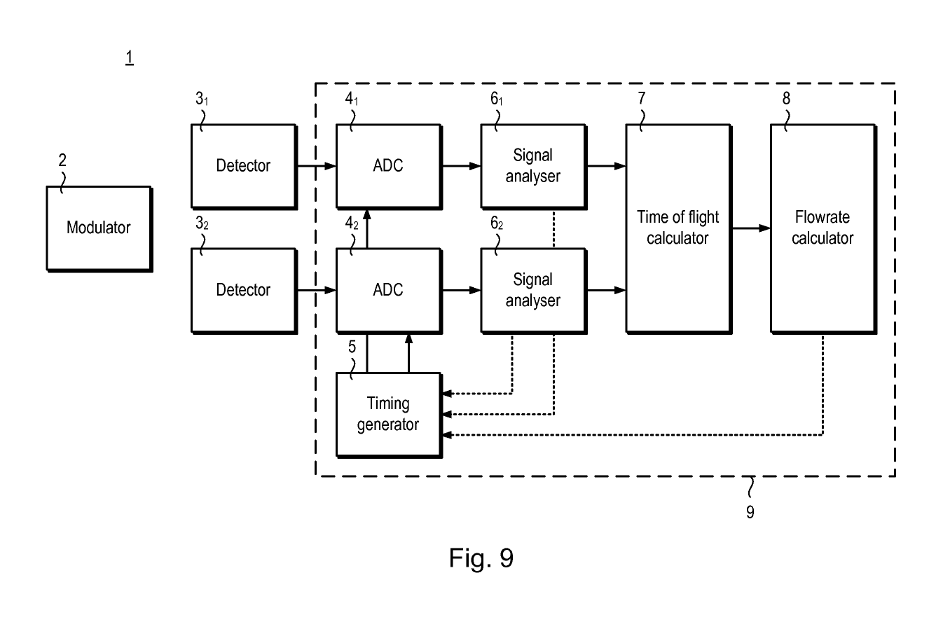

FIG. 9 illustrates an ionisation flow meter 1 in accordance with the present invention. The ionisation flow meter 1 is similar to that described in WO 2007 068869 A ibid. in that the flow meter 1 includes a conduit (not shown), ioniser (not shown), modulating electrode structure 2 and detector electrodes 3₁, 3₂ which are structured, arranged and operated as described in WO 2007 068869 A ibid.

The detectors 3₁, 3₂ generate respective signals which are supplied to respective analog-to-digital converters 4₁, 4₂ (hereinafter “ADCs”). The sampling rates of the ADCs 4₁, 4₂ are controlled by a timing generator 5 which supplies a trigger signal to the ADCs 4₁, 4₂ for single sampling, for example by enabling an ADC clock, switching on a sample and hold circuit (if used), by triggering conversion, or a combination of these techniques. The timing generator 5 varies the clock rate in the manner hereinbefore described over the period of the signal (beginning at a start time t_{α} and ending at a finish time t_{ω}) corresponding to one modulation cycle. Preferably, the signal has only one peak in the period.

The ADCs 4₁, 4₂ outputs respective sets of samples, for example in a stream or as a block, which are supplied to signal analysers 6₁, 6₂. A signal analyser 6₁, 6₂ resolves a peak within a set of samples and estimates peak position, for example using a quadratic curve fitting process.

The signal analysers 6₁, 6₂ output peak positions which are fed into a time-of-flight calculator 7 to measure time of flight.

The time-of-flight calculator 7 outputs a value which is provided to a flow rate calculator 8 to calculate a volumetric flow rate of gas passing through the system at a given time.

Once one cycle has been completed, the clock rate is reset and the process is repeated for the next cycle.

The ADCs 4₁, 4₂, timing generator 5, signal analysers and calculators 7, 8 can be conveniently implemented by a microcontroller 9.

Reducing the number of samples can help to save power, to reduce the amount of processing power required and/or to reduce the amount of memory used. This can benefit embedded systems which use small, inexpensive microcontrollers.

It will be appreciated that many modifications may be made to the embodiments hereinbefore described. For example, external ADC(s) can be used. A single ADC module having multiple channels can be used.

In some embodiments, the timing generator can output variable clock rates according to measured flow rates. As flow rate changes, the shape of the signal changes and so a particular value of k used to generate a sampling rate may no longer provide the best fit, for example, either because the peak includes too few or too many samples. Thus, the timing generator may receive feed back from the signal analyser and/or from the flowrate calculator and select a new value of k. The timing generator may include a table listing flow rates and either corresponding values of k which can be used to compute clock rates or corresponding sets of pre-computed clock rates.

In some examples, two sensors may not be needed. For example, the start time of time of a time-of-flight measurement may be known or inferred. Thus, one sensor and one ADC may be used.

In some applications, a monotonically decreasing function may be used. Accordingly, exponents (such as k) are negative.

Varying the sampling rate of an ADC can be used in other types of sensing devices, systems and applications. For example, the device may be any form of tracer flow measurement device, such as a thermal mass flow controller. Varying the sampling rate of an ADC can be used in sonar systems, such as range finders and seismic geotechnical survey equipment. It can be used in resonance-based sensing systems, such as tuning fork sensors. It can be used in impulse-based measurement systems, such as gunshot localisation systems. It can be used in hearing aid channel measurement systems for equalisation. It can be used in collision avoidance radar and in laser range finders.

1. A system for processing a signal from a sensor, the system comprising an analog-to-digital converter, wherein the system is configured to vary a sampling rate of said analog-to-digital converter dependent on an expected shape of the signal.

2. A system according to claim 1, wherein a sample time, tₙ, of an n-th sample follows a relationship:
tₙ=func(n)
where func(n) is a monotonic function.

3. A system according to claim 1, wherein sample times increases at a rate faster than arithmetic progression.

4. A system according to claim 1, wherein a sample time, tₙ, of an n-th sample follows the relationship:
tₙ=a+t₀e^{kn}
where a is an offset which can be zero, i.e. a=0, or positive, i.e. a>0, t₀ is an initial sample time and k is greater than 0, i.e. k>0.

5. A system according to claim 4, wherein:
$$k = \frac{1}{N} \cdot log ( \frac{{t}_{B}}{{t}_{A}} )$$
wherein (N+1) is a number of desired points within a top half of a signal peak lying between expected values t_{A}, and t_{B}.

6. A system according to claim 5, wherein (N+1) is at least 3.

7. A system according to claim 5, wherein (N+1) is no more than 10 and, optionally, no more than 5.

8. A system according to claim 3, wherein k is no more than 0.5 and, optionally, no more than about 0.3.

9. A system according to claim 3, wherein k is greater than 0.05.

10. A system according to claim 1, wherein a sample time, tₙ, of an n-th sample follows the relationship:
tₙ=a+t₀kⁿ
where a is an offset which can zero, i.e. a=0, or positive, i.e. a>0, t₀ is an initial sample time and k is greater than 1, i.e. k>0.

11. A system according to claim 1, wherein a sample time, tₙ, of an n-th sample follows the relationship:
tₙ=a+t₀n^{p}
where a is an offset which can be zero or positive, i.e. a≦0, t₀ is an initial sample time and p is greater than 1.

12. A system according to claim 1, which is microcontroller.

13. Apparatus comprising:
a sensor; and
a system according to claim 1,
wherein the system operationally connected to the sensor such that, when the sensor generates a signal, the signal is received by the analog-to-digital convertor.

14. Apparatus according to claim 13, which is flow meter.

15. A method, comprising:
receiving an analog signal; and
digitally sampling the analog signal;
wherein the analog signal is sampled at a varying sample rate which depends on an expected shape of the signal.

16. A method according to claim 15, wherein a time interval between samples increases monotonically.
